(19) United States
(12) Patent Application Publication
(10) Pub. No.: US 2018/0235110 A1
(43) Pub. Date: Aug. 16, 2018

(54) COOLING SYSTEM FOR RF POWER ELECTRONICS

(71) Applicant: Lam Research Corporation, Fremont, CA (US)

(72) Inventors: Sudhakar GOPALAKRISHNAN, San Jose, CA (US); Peter REIMER, San Jose, CA (US); John HARUFF, San Jose, CA (US); John DAUGHERTY, Fremont, CA (US)

(21) Appl. No.: 15/435,178

(22) Filed: Feb. 16, 2017

(51) Int. Cl. H05K 7/20; H01L 21/673; H01L 21/683; H01L 21/67

(52) U.S. Cl. CPC H05K 7/20945; H01L 21/67383; H01L 21/6833; H05K 7/20918; H01L 21/67248; H01L 21/67389; H01L 21/67069

(57) ABSTRACT

A cooling apparatus is provided. At least one power electronic component is provided. A fluid tight enclosure surrounds the at least one power electronic component. An inert dielectric fluid at least partially fills the fluid tight container and is in contact with the at least one power electronic component.

### BACKGROUND

The disclosure relates to a method of forming semiconductor devices on a semiconductor wafer. More specifically, the disclosure relates to systems for plasma or non-plasma processing semiconductor devices.

In forming semiconductor devices, stacks are subjected to processing in a plasma processing chamber. Such chambers use RF power generators to create and maintain a plasma.

### SUMMARY

To achieve the foregoing and in accordance with the purpose of the present disclosure, a cooling apparatus is provided. At least one power electronic component is provided. A fluid tight enclosure surrounds the at least one power electronic component. An inert dielectric fluid at least partially fills the fluid tight container and is in contact with the at least one power electronic component.

In another manifestation, an apparatus for processing a substrate is provided. A processing chamber is provided. A substrate support supports a substrate within the processing chamber. A gas source is provided. A gas inlet is in fluid connection between the gas source and the processing chamber. A power source for provides RF power into the processing chamber, comprising RF power electronic components for providing RF power, and a cooling system for cooling the RF power electronic components, comprising a cooling chamber surrounding the RF power electronic components and a pump for circulating coolant within the cooling chamber.

These and other features of the present invention will be described in more details below in the detailed description of the invention and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic view of a plasma processing chamber that may be used in an embodiment.

FIG. 2 is a more detailed view of a power source.

FIG. 3 is a more detailed view of a power source in another embodiment.

FIG. 4 is a more detailed view of a power source in another embodiment.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

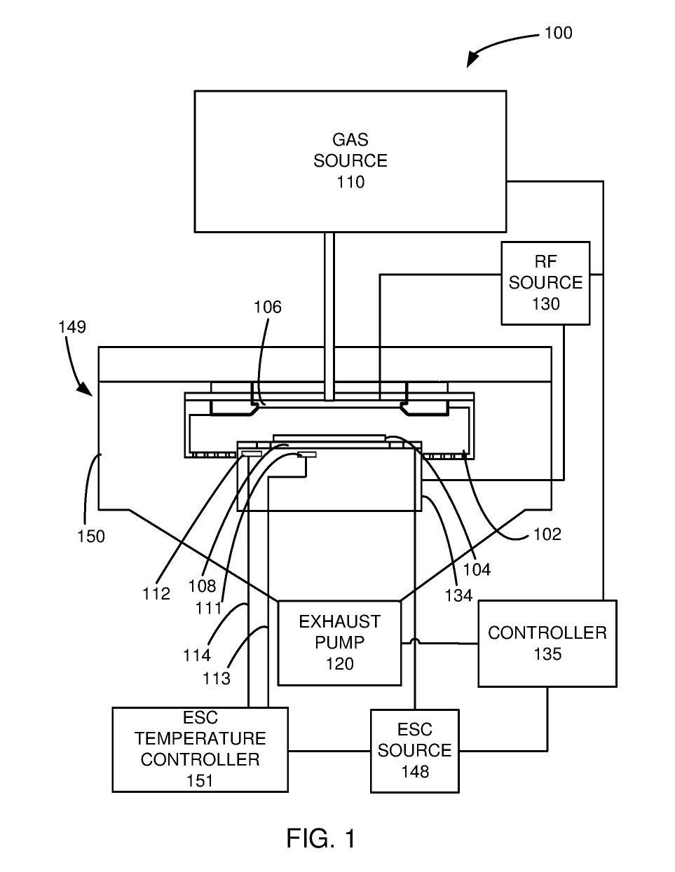

FIG. 1 is a schematic view of a plasma processing chamber that may be used in an embodiment. In one or more embodiments, the plasma processing chamber 100 comprises a gas distribution plate 106 providing a gas inlet and an electrostatic chuck (ESC) 108, within a processing chamber 149, enclosed by a chamber wall 150. Within the processing chamber 149, a substrate 104 is positioned on top of the ESC 108. The ESC 108 may provide a bias from the ESC source 148. A gas source 110 is connected to the processing chamber 149 through the distribution plate 106. An ESC temperature controller 151 is connected to the ESC 108, and provides temperature control of the ESC 108. In this example, a first connection 113 provides power to an inner heater 111 for heating an inner zone of the ESC 108 and a second connection 114 provides power to an outer heater 112 for heating an outer zone of the ESC 108. An RF source 130 provides RF power to a lower electrode 134 and an upper electrode, which in this embodiment is the gas distribution plate 106. In a preferred embodiment, 2 MHz, 60 MHz, and optionally, 27 MHz power sources make up the RF source 130 and the ESC source 148. In this embodiment, one generator is provided for each frequency. In other embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments, such as in another embodiment the upper electrodes may be grounded. A controller 135 is controllably connected to the RF source 130, the ESC source 148, an exhaust pump 120, and the etch gas source 110. An example of such a etch chamber is the Exelan Flex™ etch system manufactured by Lam Research Corporation of Fremont, Calif. The process chamber can be a CCP (capacitive coupled plasma) reactor or an ICP (inductive coupled plasma) reactor.

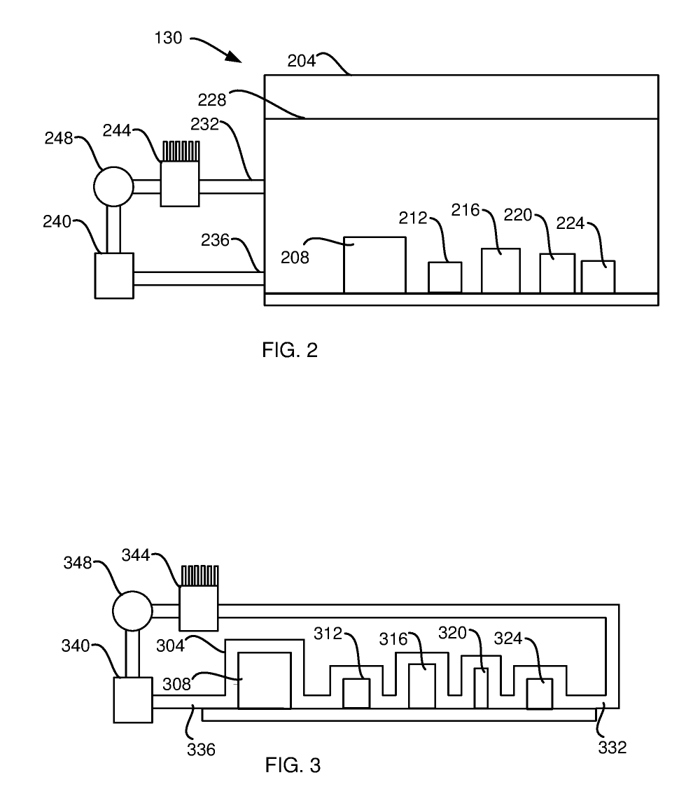

FIG. 2 is a more detailed view of the RF source 130. In this embodiment, the RF source 130 comprises a fluid tight enclosure 204. At the bottom of the fluid tight enclosure are mounted RF power electronic components. In this embodiment, the RF power electronic components comprise a power source 208, an oscillator 212, an amplifier 216, an attenuator 220, and a level controller 224. The fluid tight enclosure is at least partially filled with an inert dielectric fluid 228. A fluid outlet 232 is in fluid connection with the fluid tight enclosure 204 and the inert dielectric fluid 228. A fluid inlet 236 is in fluid connection with the fluid tight enclosure 204 and the inert dielectric fluid 228. A pump 240 is in fluid connection between the fluid outlet 232 and the fluid inlet 236. A heat exchanger 244 and a temperature sensor 248 are also in fluid connection between the fluid inlet 232 and the fluid outlet 232. The dielectric fluid 228 is in direct contact with the RF power electronic components.

In this embodiment, the pump 240 is a particle free pump, such as a magnetic levitation (maglev) pump. The inert dielectric fluid 228 is a fluorinated oxygen free fluid, such as Gladen® Heat Transfer Fluid HT 110 by Kurt J. Lesker Company, Jefferson Hills, Pa.

In operation, a substrate 104 is mounted on the ESC 108. A process gas is flowed from the gas source 110 into the processing chamber 149. The pump 240 pumps the dielectric fluid 228 from the fluid tight enclosure 204 through fluid outlet 232, the heat exchanger 244, and the temperature sensor 248 to the fluid inlet 236, which directs the dielectric fluid 228 back into the fluid tight enclosure 204. RF power is provided from the RF power source 130 to the ESC 108 to form the process gas into a plasma.

Gladen® Heat Transfer Fluid HT 110 is FM 6930 approved and provides sufficient cooling without damaging the RF power electronic components. The maglev pump 240 recirculates the dielectric fluid 228 without adding particulates, which could damage the RF power electronic components, by possibly shorting the components. In addition, the maglev pump is frictionless, which reduces heat generated by the pump. The heat exchanger 244 dissipates heat from the dielectric fluid 228. The temperature sensor 248 may be used to determine if the system is working properly. If there is component overheating due to a malfunction, smoking is prevented, because the dielectric fluid is oxygen free. The component may cause the dielectric fluid to vaporize, but would be smoke free, due to the lack of oxygen. The dielectric fluid has more than three times the heat conductivity of air, and prevents moisture from reaching the RF power electronic components. In addition, the dielectric fluid has a heat capacitance much higher than air. In this embodiment, the heat exchanger 244 uses Peltier cooling. Such Peltier cooling may use cooling fins. Cooling fans may be avoided, since fans may be a source of particle generation in a clean room. The use of a maglev pump and cooling fins for cooling instead of a cooling fan reduces noise. Since this embodiment is smoke free at failure, a higher power may be provided without the danger of creating smoke.

The direct contact between the dielectric fluid 228 and the RF power electronic components keeps the RF power electronic components sufficiently cool to prevent the RF power electronic components from smoking or failing. The presence of smoke during the plasma processing is a fire hazard and may create contaminants which would interfere with semiconductor fabrication.

Preferably, the fluid system is a sealed system. A diaphragm may be used to adjust for changing pressure. The level controller 224 may receive input from the temperature sensor 248 to shut down the system if the temperature is elevated above a threshold temperature, indicating a system failure.

Inert dielectric fluids have a high electrical resistivity and high dielectric strength. An inert dielectric fluid has a dielectric strength value of at least 10⁶ V/m and electrical resistivity of at least 10¹⁰ ohm-cm.

FIG. 3 is a more detailed view of the RF source in another embodiment. In this embodiment, the RF source comprises a shrink fluid tight enclosure 304. In the fluid tight enclosure are mounted RF power electronic components. In this embodiment, the RF power electronic components comprise a power source 308, an oscillator 312, an amplifier 316, an attenuator 320, and a level controller 324. The fluid tight enclosure is at least partially filled with an inert dielectric fluid. A fluid outlet 332 is in fluid connection with the fluid tight enclosure 304 and the inert dielectric fluid. A fluid inlet 336 is in fluid connection with the fluid tight enclosure and the inert dielectric fluid. A pump 340 is in fluid connection between the fluid outlet 332 and the fluid inlet 336. A heat exchanger 344 and a temperature sensor 348 are also in fluid connection between the fluid outlet 332 and the fluid inlet 336. The dielectric fluid 328 is in direct contact with the RF power electronic components. This embodiment provides a smaller profile power source. In addition, by providing a near net shape flow contour to the electronic components the liquid velocity may be increased and the volume of cooling liquid may be decreased. In other embodiments, the shrink fit enclosure may be replaced with any fluid type enclosure with contours that match the contours of the electronic components or the electronic assembly formed by the electronic components.

Preferred embodiments use a single phase cooling process, since single phase cooling may be used to remove larger amounts of heat. In other embodiments, a micro electromechanical systems (MEMS) micropump may be used. In other embodiments, multiple inlets and/or multiple outlets may be used. In some embodiments, the controller may switch on the pump when a threshold temperature is measured. If a diaphragm is used, the diaphragm may be connected to a sensor. Preferably, the pump generates minimal particles. More preferably, the pump is particle free.

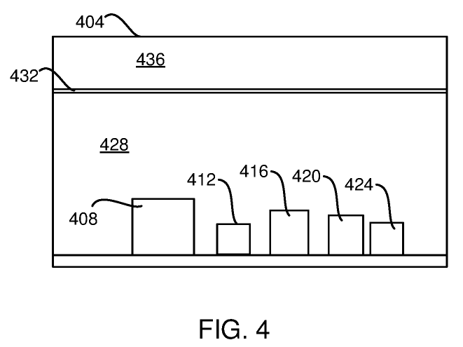

FIG. 4 is a more detailed view of the RF source in another embodiment. In this embodiment, the RF source comprises an enclosure 404. At the bottom of the enclosure 404 are mounted RF power electronic components. The dielectric fluid 428 is in direct contact with the RF power electronic components. In this embodiment, the RF power electronic components comprise a power source 408, an oscillator 412, an amplifier 416, an attenuator 420, and a level controller 424. The enclosure is filled with an inert dielectric fluid 428. A membrane 432 is over the inert dielectric fluid 428. A layer of water 436 is over the membrane 432.

If the enclosure is fluid tight, the water 436 acts as a heat sink and limited heat exchanger. If the enclosure is not fluid tight, allowing vaporized water to escape, then the vaporizing water acts as a heat sink and more as a heat exchanger.

In other embodiments, the fluid may be a silicone oil or other dielectric fluid. Fluorinated fluids are preferred, because such fluids tend to be more inert. Oxygen free fluids prevent smoking. In some embodiments, the pump is immersed in the fluid in the fluid tight enclosure. In such a case, the fluid inlet and fluid outlet are in fluid connection with the fluid, although the fluid inlet and fluid outlet are not connected to an enclosure wall.

Other power electronic components may be used in other embodiments. Power electronic components are electronic components used in a power electronic assembly for generating RF or microwave signals for providing and/or sustaining a plasma, and AC and/or DC power supplies for ESC, Pedestals, and other high power supplies for components adjacent to and/or in a semiconductor processing chamber. Power electronic components may operate at temperatures above 90° C. A power electronic component is defined in the specification and claims as an electronic component that is able to operate at a high power of at least 100 Watts in a clean room environment, so that power electronic component is made to receive at least 100 Watts of power. The requirements for cooling power electronic components in a clean room for semiconductor manufacturing are different than the requirements for cooling a CPU or memory in a computer system. CPUs or memory in a computer system operates at temperatures below 50° C. Computer systems do not have the same particle generation limits required by a clean room. In addition, computer systems do not have the same heat transfer requirements as power electronic components. In other embodiments, the electronic components may be used in a non-plasma processing chamber.

In some embodiments, a cooling fluid flow rate above 0.31 m/s is preferred. More preferably, the flow rate is between 0.31 m/s and 0.96 m/s. Most preferably, the cooling fluid flow rate is sufficient to cause turbulent flow. Such a turbulent flow would occur at the above flow rate when the fluid Reynold's Numbers are greater than 4000. In addition, the power electronics preferably provide an irregular profile that further increased turbulence. For CPU and memory, which operate at lower temperatures, a slower flow rate is used to provide laminar flow, since in such situations laminar flow is more desirable.

While this invention has been described in terms of several preferred embodiments, there are alterations, modifications, permutations, and various substitute equivalents, which fall within the scope of this invention. It should also be noted that there are many alternative ways of implementing the methods and apparatuses of the present invention. It is therefore intended that the following appended claims be interpreted as including all such alterations, modifications, permutations, and various substitute equivalents as fall within the true spirit and scope of the present invention.

What is claimed is:

1. A cooling apparatus, comprising:
at least one power electronic component;
a fluid tight enclosure surrounding the at least one power electronic component; and
an inert dielectric fluid at least partially filling the fluid tight container and in contact with the at least one power electronic component.

2. The cooling apparatus, as recited in claim 1, further comprising,
an inlet fluid connection in fluid connection with the inert dielectric fluid;
an outlet fluid connection in fluid connection with the inert dielectric fluid;
a pump in fluid connection between the fluid inlet and fluid outlet.

3. The cooling apparatus, as recited in claim 2, further comprising a temperature sensor thermally connected to the inert dielectric fluid to measure the temperature of the inert dielectric fluid.

4. The cooling apparatus, as recited in claim 3, wherein the pump is a particle free pump.

5. The cooling apparatus, as recited in claim 4, wherein the inert dielectric fluid is a fluorinate fluid.

6. The cooling apparatus, as recited in claim 5, wherein the inert dielectric fluid is oxygen free.

7. The cooling apparatus, as recited in claim 6, wherein the at least one power electronic component is an electronic component for receiving at least 100 Watts of power.

8. The cooling apparatus, as recited in claim 6, wherein the at least one power electronic component is used in ESC, pedestal heaters, semiconductor processing chamber heating and other adjacent devices and is for receiving at least 100 Watts of power.

9. The cooling apparatus, as recited in claim 2, wherein the pump provides a fluid flow at the at least one power electronic component with a velocity of at least 0.31 m/s.

10. The cooling apparatus, as recited in claim 2, wherein the pump provides a turbulent fluid flow around the at least one power electronic component.

11. The cooling apparatus, as recited in claim 1, further comprising a heat exchanger in thermal contact with the inert dielectric fluid.

12. The cooling apparatus, as recited in claim 1, wherein the inert dielectric fluid is a fluorinate fluid.

13. The cooling apparatus, as recited in claim 1, wherein the inert dielectric fluid is oxygen free.

14. The cooling apparatus, as recited in claim 1, wherein the at least one power electronic component is an electronic component for receiving at least 100 Watts of power.

15. The cooling apparatus, as recited in claim 1, wherein the at least one power electronic component operates at an operating temperature above 90° C.

16. An apparatus for processing a substrate, comprising:
a processing chamber;
a substrate support for supporting a substrate within the processing chamber;
a gas source;
a gas inlet in fluid connection between the gas source and the processing chamber;
a power source for providing RF power into the processing chamber, comprising:
RF power electronic components for providing RF power; and
a cooling system for cooling the RF power electronic components, comprising;
a cooling chamber surrounding the RF power electronic components; and
a pump for circulating coolant within the cooling chamber.

17. The apparatus, as recited in claim 16, wherein the pump provides a turbulent fluid flow around the RF power electronic components.
